(19) United States
(12) Patent Application Publication
(10) Pub. No.: US 2023/0157050 A1
(43) Pub. Date: May 18, 2023

(54) DISPLAY DEVICE

(71) Applicant: Japan Display Inc., Tokyo (JP)

(72) Inventor: Toshiki KANEKO, Tokyo (JP)

(73) Assignee: Japan Display Inc., Tokyo (JP)

(21) Appl. No.: 17/986,944

(22) Filed: Nov. 15, 2022

(30) Foreign Application Priority Data
Nov. 15, 2021 (JP) 2021-185743

(51) Int. Cl. H01L 51/52

(52) U.S. Cl. CPC H01L 51/5209; H01L 51/5218; H01L 2251/5315

(57) ABSTRACT

According to one embodiment, a display device includes a base, a first insulating layer disposed on the base, a lower electrode disposed on the first insulating layer, an organic layer disposed on the lower electrode and including a light-emitting layer and an upper electrode disposed on the organic layer, and the lower electrode includes a conductive layer including a contact area disposed over an entire circumference thereof when viewed in plan view, a reflective layer disposed above the conductive layer on an inner side of the contact area, which reflects light and a transparent electrode located on the conductive layer and the reflective layer and in contact with the contact area.

### CROSS-REFERENCE TO RELATED APPLICATIONS

This application is based upon and claims the benefit of priority from Japanese Patent Application No. 2021-185743, filed Nov. 15, 2021, the entire contents of which are incorporated herein by reference.

### FIELD

Embodiments described herein relate generally to a display device.

### BACKGROUND

In recent years, display devices comprising organic light-emitting diodes (OLEDs) applied thereto as display elements have been put to practical use. Display devices having a top emission structure includes a high-reflective electrode which increases the reflectivity to resonate light, that is, for example, a reflective electrode containing silver (Ag), and a transparent electrode having a large band gap and located on the high-reflective electrode, that is, for example, an anode (or anode electrode) containing indium tin oxide (ITO) or indium zinc oxide (ZnO). To increase the resolution of such a display device, for example, from 300 ppi to 3,000 ppi, dry etching, which can be used in microfabrication, may be employed for processing the display device. Note that wet dry etching is not suitable for such process. However, since it is difficult to process a reflective electrode containing silver (Ag) by dry etching, the reflective electrode needs to be formed of aluminum (Al) or the like. Then, again, it is also difficult to achieve electrical contact between aluminum (Al) and a transparent electrode, for example, indium tin oxide (ITO). Under these circumstances, between aluminum (Al) and the transparent electrode, for example, a conducting electrode having good electrical contact with the transparent electrode, for example, indium tin oxide (ITO) needs to be placed. However, such a conducting electrode having good electrical contact with the transparent electrode, for example, indium tin oxide (ITO) needs to be placed between aluminum (Al) and the transparent electrode, may cause lowering in reflectivity on the surface of the anode. As a result, the absorption of light during multiple reflections on the surface of the anode is increased, and therefore the light-emission efficiency of the display device can be reduced.

### BRIEF DESCRIPTION OF THE DRAWINGS

FIG. 1 is a diagram showing a configuration example of a display device according to the first embodiment.

FIG. 2 is a plan view of a configuration example of a pixel according to the first embodiment.

FIG. 3 is a cross-sectional view of the configuration example of a display element according to the first embodiment.

FIG. 4 is a cross-sectional view of a configuration example of a display element according to a comparative example.

FIG. 5 is a schematic diagram showing an example of a brightness-voltage curve.

FIG. 6 is a cross-sectional view showing a configuration example of a display element according to a modified example 1.

FIG. 7 is a cross-sectional view showing a configuration example of a display element according to a modified example 2.

FIG. 8 is a cross-sectional view showing a configuration example of a display element according to a modified example 3.

FIG. 9 is a cross-sectional view showing a configuration example of a display element according to a modified example 4.

FIG. 10 is a cross-sectional view showing a configuration example of a display element according to a modified example 5.

FIG. 11 is a cross-sectional view showing a configuration example of a display element according to the second embodiment.

FIG. 12 is a cross-sectional view showing a configuration example of a display element according to a modified example 6.

FIG. 13 is a cross-sectional view showing a configuration example of a display element according to a modified example 7.

FIG. 14 is a cross-sectional view showing a configuration example of a display element according to a modified example 8.

### DETAILED DESCRIPTION

In general, according to one embodiment, a display device comprises a base, a first insulating layer disposed on the base, a lower electrode disposed on the first insulating layer, an organic layer disposed on the lower electrode and including a light-emitting layer and an upper electrode disposed on the organic layer, and the lower electrode includes a conductive layer including a contact area disposed over an entire circumference thereof when viewed in plan view, a reflective layer disposed above the conductive layer on an inner side of the contact area, which reflects light and a transparent electrode located on the conductive layer and the reflective layer and in contact with the contact area.

According to another embodiment, a display device comprises a base, a first insulating layer disposed on the base, a lower electrode disposed on the first insulating layer, an organic layer disposed on the lower electrode and including a light-emitting layer and an upper electrode disposed on the organic layer, and the lower electrode includes a conductive layer, a reflective layer disposed on the conductive layer, which reflects light, and a transparent electrode disposed on the reflective layer, the transparent electrode is formed of indium tin oxide, and the reflective layer is formed of Al—Ni, Al—W alloy, Al—Mo alloy, Al—Ti alloy, Al—Ni—W, Al—Ni—Mo alloy or Al—Ni—Ti alloy.

Embodiments will be described hereinafter with reference to the accompanying drawings.

Note that, throughout the embodiments, common structural elements are denoted by the same symbols and redundant explanations are omitted. Further, the drawings are schematic diagrams to facilitate understanding of the embodiments, and the shapes, dimensions, ratios, and the like, may differ from actual conditions, but they may be redesigned as appropriate, taking into account the following descriptions and conventionally known technology.

Note that, in order to make the descriptions more easily understandable, some of the drawings illustrate an X axis, a Y axis and a Z axis orthogonal to each other. A direction along the X axis is referred to as an X direction or a first direction, a direction along the Y axis is referred to as a Y direction or a second direction and direction along the Z axis is referred to as a Z direction or a third direction. The first direction X, the second direction Y and the third direction Z may intersect each other at an angle other than 90 degrees. A length along the first direction X or the second direction Y may be referred to as a width, and the length along the third direction Z may be referred to as a thickness. In the following descriptions, a direction from a base 10 to a display element 20 may be referred to as “upward” (or simply “above”) and a direction from the display element 20 to the base 10 may be referred to as “downward” (or simply “below”). With such expressions as “a second layer above a first layer” and “a second layer below a first layer”, the second layer may be in contact with the first layer or may be remote from the first layer. A plane defined by the X axis (the first direction X) and the Y axis (the second direction Y) may be referred to as an X-Y plane, a plane defined by the X axis (the first direction X) and the Z axis (the third direction Z) may be referred to as an X-Z plane, and a plane defined by the Y axis (the second direction Y) and the Z axis (the third direction Z) may be referred to as an Y-Z plane. Further, viewing towards the X-Y plane is referred to as plan view.

### First Embodiment

This embodiment is directed to a display device DSP is an organic electroluminescent display device comprising organic light-emitting diodes (OLEDs) as display elements, and is installed in televisions, personal computers, mobile terminals, cellular phones, and other devices.

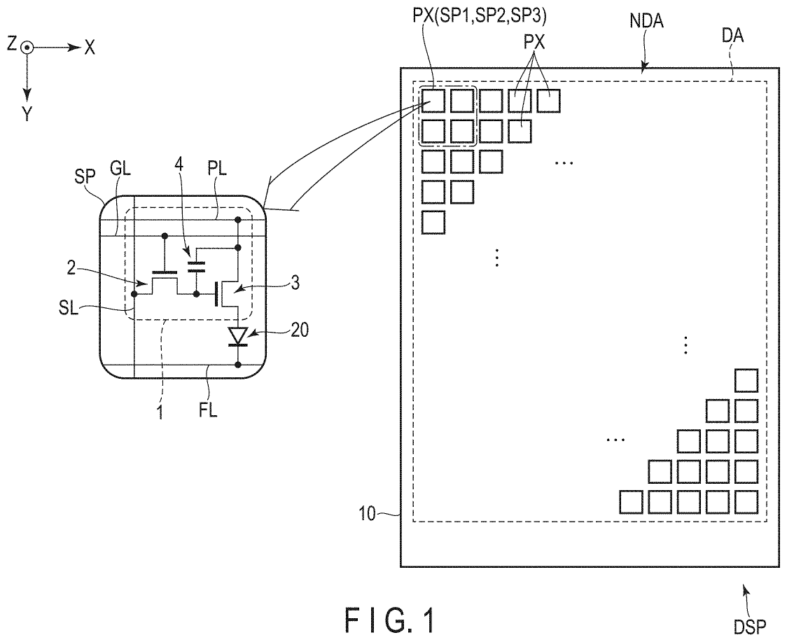

FIG. 1 is a diagram showing a configuration example of the display device DSP of this embodiment.

The display device DSP comprises an insulating base 10. The base 10 may be glass or a flexible resin film. Further, the display device DSP includes a display area DA in which images are displayed and a non-display area NDA surrounding the display area DA.

The display device DSP comprises, in the display area DA, a plurality of pixels PX arranged in a matrix along the first direction X and the second direction Y.

The pixels PX each comprise a plurality of sub-pixels SP1, SP2 and SP3. For example, the pixels PX each contain a red sub-pixel SP1, a green sub-pixel SP2 and a blue sub-pixel SP3. The pixels PX may additionally contain fourth or more sub-pixels in addition to the above-described three-color sub-pixels, of some other color such as white.

A configuration example of one sub-pixel SP contained in a pixel PX will be briefly described. That is, the sub-pixel SP comprises a pixel circuit 1 and a display element 20 driven and controlled by the pixel circuit 1. The pixel circuit 1 comprises a pixel switch 2, a drive transistor 3 and a capacitor 4. The pixel switch 2 and drive transistor 3 are switching elements constituted by, for example, thin-film transistors. The switching elements include electrodes made of, for example, titanium(Ti)-aluminum (Al)-titanium(Ti). Note that the electrodes of the switching element may as well be formed of materials other than titanium(Ti)-aluminum(Al)-titanium(Ti).

As to the pixel switch 2, the gate electrode is connected to the respective scanning line GL, the source electrode is connected to the respective signal line SL, and the drain electrode is connected to one of the electrodes which constitutes the capacitor 4 and the gate electrode of the drive transistor 3. As to the drive transistor 3, the source electrode is connected to the other electrode of the capacitor 4 and a power line PL, and the drain electrode is connected to the anode of the display element 2. The cathode of the display element 20 is connected to a power feed line FL. Note that the configuration of the pixel circuit 1 is not limited to that of the example shown in the figure.

The display element 20 is an organic light emitting diode (OLED), which is a light-emitting element. For example, the sub-pixel SP1 comprises a display element which emits light corresponding to red wavelengths, the sub-pixel SP2 comprises a display element which emits light corresponding to green wavelengths, and the sub-pixel SP3 comprises a display element which emits light corresponding to blue wavelengths. Note that the sub-pixels SP1 to SP3 may comprise a display element which emits light corresponding to white wavelengths. When the emission color of each of the display elements 20 is white, multicolor display can be realized by arranging color filters to oppose the display elements 20, respectively. When the emission color of each of the display elements 20 is of ultraviolet light, multicolor display can be realized by arranging light conversion layers to oppose the display elements 20. The configuration of the display elements 20 will be described later.

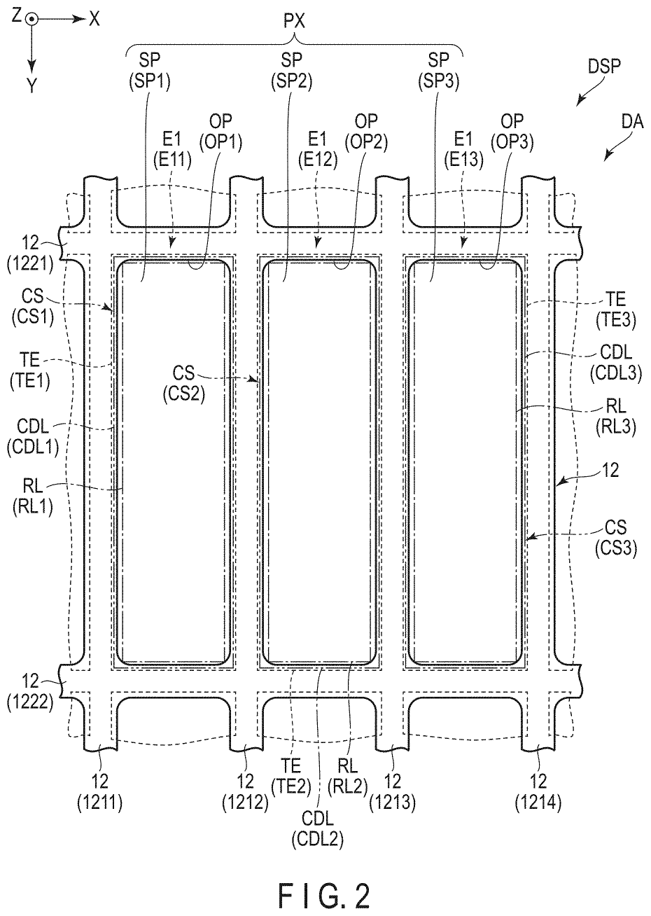

FIG. 2 is a plan view showing a configuration example of a pixel PX according this embodiment.

FIG. 2 shows only the configuration necessary for explanation.

The display device DSP comprises an insulating layer 12, a lower electrode E1 and the like. In the example shown in FIG. 2, the display device DSP comprises insulating layers 12 (1211, 1212, 1213, 1214, 1221 and 1222) and lower electrodes E1 (E11, E12 and E13), and the like.

The lower electrodes E1 are disposed in the sub-pixels SP. In the example shown in FIG. 2, the lower electrode E1 includes lower electrodes E11, E12 and E13. The lower electrode E11 is disposed in the sub-pixel SP1. The lower electrode E12 is disposed in the sub-pixel SP2. The lower electrode E13 is disposed in the sub-pixel SP3. The lower electrodes E11, E12 and E13 are aligned along the first direction X. The lower electrodes E1, including the lower electrodes E11 to E13, are electrodes disposed for each sub-pixel or each display element and may be referred to as pixel electrodes, anodes, anodes or the like.

The lower electrode E1 (E11, E12 and E13) includes a transparent electrode TE (TE1, TE2 and TE3), a reflective layer (or reflective electrode) RL (RL1, RL2 and RL3) which reflects light, and a conductive layer (or conductive electrode) CDL (CDL1, CDL2 and CDL3) which has conductivity. In the example shown in FIG. 2, the conductive layer CDL is formed into a rectangular shape (oblong or quadrangular) in plan view. The conductive layer CDL may be formed into a shape other than a rectangular shape (oblong or quadrangular) in plan view. The conductive layer CDL is formed into a rectangular shape whose length along the second direction Y is greater than the length along the first direction X in plan view. The reflective layer RL is located above the conductive layer CDL and overlaps the conductive layer CDL. In the example shown in FIG. 2, the reflective layer RL is formed into a rectangular shape (or quadrangular) in plan view. Note that the reflective layer RL may be formed into a shape other than a rectangular shape (or quadrangular) in plan view. The reflective layer RL is formed into a rectangular shape whose length along the second direction Y is greater than that along the first direction X in plan view. The size (or area) of the reflective layer RL is less than the size (or area) of the conductive layer CDL in plan view. In the example shown in FIG. 2, the reflective layer RL overlaps the central portion of the conductive layer CDL in plan view. Note that the reflective layer RL may overlap the conductive layer CDL to be off-center in plan view. The area of the conductive layer CDL where the reflective layer RL does not overlap in plan view may be referred to as a contact surface (or contact area) CS. The contact surface CS is disposed over the entire circumference (or the entire periphery) of the conductive layer CDL when viewed in plan view. Note that the contact surface CS, when viewed in plan view, may not be disposed over the entire circumference (or the entire periphery) of the conductive layer CDL. For example, the contact surface CS is disposed in a ring manner when viewed in plan view. In the example shown in FIG. 2, the reflective layer RL overlaps the conductive layer CDL when viewed in plan view and is surrounded by the contact surface CS. In other words, the reflective layer RL is disposed on an inner side of the contact surface CS when viewed in plan view. The transparent electrode TE is located above the reflective layer RL and the conductive layer CDL, and overlap the reflective layer RL and conductive layer CDL. In the example shown in FIG. 2, the transparent electrode TE is formed into a rectangular shape (oblong or quadrangular) in plan view. Note that the transparent electrode TE may be formed into a shape other than rectangular (oblong or quadrangular) in plan view. The transparent electrode TE is formed into a rectangular shape whose length along the second direction Y is greater than that along the first direction X in plan view. The size (or area) of the transparent electrode TE is greater than the size (or area) of the reflective layer RL in plan view. The size (or area) of the transparent electrode TE may be less than or equal to the size (or area) of the conductive layer CDL in plan view. The transparent electrode TE covers the reflective layer RL and the conductive layer CDL. The transparent electrode TE is in contact with, for example, the conductive layer CDL at the contact surface CS and completely covers the reflective layer RL.

The lower electrode E11 includes a transparent electrode TEl, a reflective layer (or reflective electrode) RL1 and a conductive layer (or conductive electrode) CDL1. In the example shown in FIG. 2, the conductive layer CDL1 is formed into a rectangular shape (oblong or quadrangular) in plan view. Note that the conductive layer CDL1 may be formed into a shape other than a rectangular shape (oblong or quadrangular) in plan view. The conductive layer CDL1 is formed into a rectangular shape whose length along the second direction Y is greater than that of the first direction X in plan view. The reflective layer RL1 is located above the conductive layer CDL1 and overlaps the conductive layer CDLl. In the example shown in FIG. 2, the reflective layer RL1 is formed into a rectangular shape (oblong or quadrangular shape) in plan view. Note that the reflective layer RL1 may be formed into a shape other than a rectangular shape (oblong or quadrangular) in plan view. The reflective layer RL1 is formed into a rectangular shape whose length along the second direction Y is greater than that along the first direction X in plan view. The size (or area) of the reflective layer RL1 is less than the size (or area) of the conductive layer CDL1 in plan view. In the example shown in FIG. 2, the reflective layer RL1 overlaps the central portion of the conductive layer CDL1 in plan view. Note that the reflective layer RL1 may overlap the conductive layer CDL1 to be off-center in plan view. In the example shown in FIG. 2, the reflective layer RL1, when viewed in plan view, overlaps the conductive layer CDL1 and is surrounded by the contact surface CS1. In other words, the reflective layer RL1 is disposed on an inner side of the contact surface CS1 when viewed in plan view. The transparent electrode TE1 is located above the reflective layer RL1 and the conductive layer CDL1 and overlaps the reflective layer RL1 and the conductive layer CDLl. In the example shown in FIG. 2, the transparent electrode TEl is formed into a rectangular shape (oblong or quadrangular) in plan view. Note that the transparent electrode TEl may be formed into a shape other than a rectangular shape (oblong or quadrangular shape) in plan view. The transparent electrode TEl is formed into a rectangular shape whose length along the second direction Y is greater than the length along the first direction X in plan view. The size (or area) of the transparent electrode TEl is larger than that of the reflection layer RL1 in plan view. Note that the size (or area) of the transparent electrode TEl may be less than or equal to the size (or area) of the conductive layer CDL1 in plan view. The transparent electrode TE1 covers the reflective layer RL1 and the conductive layer CDL1. The transparent electrode TEl is in contact with, for example, the conductive layer CDL1 at the contact surface CS1 and completely covers the reflective layer RL1.

The lower electrode E12 includes a transparent electrode TE2, a reflective layer (or reflective electrode) RL2 and a conductive layer (or conductive electrode) CDL2. In the example shown in FIG. 2, the conductive layer CDL2 is formed into a rectangular shape (oblong or quadrangular) in plan view. The conductive layer CDL2 may be formed into a shape other than a rectangular shape (oblong or quadrangular shape) in plan view. The conductive layer CDL2 is formed into a rectangular shape whose length along the second direction Y is greater than the length along the first direction X in plan view. The reflective layer RL2 is located above the conductive layer CDL2 and overlaps the conductive layer CDL2. In the example shown in FIG. 2, the reflective layer RL2 is formed into a rectangular shape (oblong or quadrangular shape) in plan view. The reflective layer RL2 may be formed into a shape other than a rectangular shape (oblong or quadrangular) in plan view. The reflective layer RL2 is formed into a rectangular shape whose length along the second direction Y is greater than the length along the first direction X in plan view. The size (or area) of the reflective layer RL2 is less than the size (or area) of the conductive layer CDL2 in plan view. In the example shown in FIG. 2, the reflective layer RL2 overlaps the central portion of the conductive layer CDL2 in plan view. The reflective layer RL2 may overlap the conductive layer CDL2 to be off-center in plan view. In the example shown in FIG. 2, the reflective layer RL2, when viewed in plan view, overlaps the conductive layer CDL2 and is surrounded by the contact surface CS2. In other words, the reflective layer RL2 is disposed on an inner side of the contact surface CS2 when viewed in plan view. The transparent electrode TE2 is located above the reflective layer RL2 and the conductive layer CDL2 and overlaps the reflective layer RL2 and the conductive layer CDL2. In the example shown in FIG. 2, transparent electrode TE2 is formed into a rectangular shape (oblong or quadrangular) in plan view. The transparent electrode TE2 may be formed into a shape other than a rectangular shape (oblong or quadrangular shape) in plan view. The transparent electrode TE2 is formed in a rectangular shape whose length along the second direction Y is greater than the length along the first direction X in plan view. The size (or area) of the transparent electrode TE2 is greater than that of the reflection layer RL2 in plan view. The size (or area) of the transparent electrode TE2 may be smaller than or equal to the size (or area) of the conductive layer CDL2 in plan view. The transparent electrode TE2 covers the reflective layer RL2 and the conductive layer CDL2. The transparent electrode TE2 is in contact with, for example, the conductive layer CDL2 at contact surface CS2 and completely covers the reflective layer RL2.

The lower electrode E13 includes a transparent electrode TE3, a reflective layer (or reflective electrode) RL 3 and a conductive layer (or conductive electrode) CDL3. In the example shown in FIG. 2, the conductive layer CDL3 is formed into a rectangular shape (oblong or quadrangular) in plan view. Note that the conductive layer CDL3 may be formed into a shape other than rectangular (oblong or quadrangular) in plan view. The conductive layer CDL3 is formed into a rectangular shape whose length along the second direction Y is greater than the length along the first direction X in plan view. The reflective layer RL3 is located above the conductive layer CDL3 and overlaps the conductive layer CDL3. In the example shown in FIG. 2, the reflective layer RL3 is formed into a rectangular shape (oblong or quadrangular) in plan view. Note that the reflective layer RL3 may be formed into a shape other than a rectangular shape (oblong or quadrangular) in plan view. The reflective layer RL3 is formed into a rectangular shape whose length along the second direction Y is greater than the length in the first direction X in plan view. The size (or area) of the reflective layer RL3 is less than the size (or area) of the conductive layer CDL3 in plan view. In the example shown in FIG. 2, the reflective layer RL3 overlaps the central portion of the conductive layer CDL3 in plan view. Note that the reflective layer RL3 may overlap the conductive layer CDL3 to be off-center in plan view. In the example shown in FIG. 2, the reflective layer RL3, when viewed in plan view, overlaps the conductive layer CDL3 and is surrounded by the contact surface CS3. In other words, the reflective layer RL3 is disposed on an inner side of the contact surface CS3 when viewed in plan view. The transparent electrode TE3 is located above the reflective layer RL3 and the conductive layer CDL3 and overlaps the reflective layer RL3 and the conductive layer CDL3. In the example shown in FIG. 2, the transparent electrode TE3 is formed into a rectangular shape (oblong or quadrangular) in plan view. Note that the transparent electrode TE3 may be formed into a shape other than a rectangular shape (oblong or quadrangular shape) in plan view. The transparent electrode TE3 is formed into a rectangular shape whose length along the second direction Y is greater than the length along the first direction X. The size (or area) of the transparent electrode TE3 is greater than that of the reflection layer RL3 in plan view. Note that the size (or area) of the transparent electrode TE3 may be less than or equal to the size (or area) of the conductive layer CDL3 in plan view. The transparent electrode TE3 covers the reflective layer RL3 and the conductive layer CDL3. The transparent electrode TE3 is in contact with, for example, the conductive layer CDL3 at the contact surface CS3 and completely covers the reflective layer RL3.

The insulating layer 12 is formed into a grid pattern in plan view. The insulating layer 12 is formed to compartmentalize display elements or sub-pixels and may be referred to as banks, ribs, partition walls or the like. In the example shown in FIG. 2, the insulating layer 12 includes insulating layers (banks) 1211, 1212, 1213, 1214, 1221 and 1222. The insulating layers 1211, 1212, 1213 and 1214 extend along the second direction Y. The insulating layers 1211 to 1214 are arranged to be spaced apart from each other along the first direction X. The insulating layers 1211, 1212, 1213 and 1214 are aligned in the order listed toward the tip end of the arrow along the first direction X. The insulating layers 1221 and 1222 extend along the first direction X. The insulating layers 1221 and 1222 are arranged to be spaced apart from each other along the second direction Y. For example, the insulating layers 1221 and 1222 are aligned in the order listed toward the tip end of the arrow along the second direction Y. The insulating layers 1211 to 1214 and the insulating layers 1221 and 1222 intersect each other, respectively. The insulating layer 12 comprises an opening OP overlapping the lower electrode El. In the example shown in FIG. 2, when viewed in plan view, the size (or area) of the opening OP is less than or equal to the size (or area) of the conductive layer CDL and is greater than or equal to the size (or area) of the reflective layer RL. Note that the size (or area) of the opening OP may be greater than the size (or area) of the conductive layer CDL. Further, the size (or area) of the opening OP may be less than the size (or area) of the reflective layer RL. In the example shown in FIG. 2, the insulating layer 12 includes an opening OP1 overlapping the lower electrode E11, an opening OP2 overlapping the lower electrode E12 and an opening OP3 overlapping the lower electrode E13. When viewed in plan view, the size (or area) of the opening OP1 is less than or equal to the size (or area) of the conductive layer CDL1 and is greater than or equal to the size (or area) of the reflective layer RL1. The size (or area) of the opening OP1 may be greater than the size (or area) of the conductive layer CDL1. The size (or area) of the opening OP1 may be less than the size (or area) of the reflective layer RL1. The opening OP1 corresponds to the area surrounded by the insulating layers 1211 and 1212 and the insulating layers 1221 and 1222 In other words, the central portion of the lower electrode E11, overlaps the opening OP1, is exposed from the insulating layer 12. The corners of the opening OP1 are rounded (or to have R (radius)). The corners of the opening OP1 may not be rounded or may intersect at right angles. When viewed in plan view, the size (or area) of the opening OP2 is less than or equal to the size (or area) of the conductive layer CDL2 and is larger than or equal to the size (or area) of the reflective layer RL2. Note that the size (or area) of the opening OP2 may be larger than the size (or area) of the conductive layer CDL2. The size (or area) of the opening OP2 may be less than the size (or area) of the reflective layer RL2. The opening OP2 corresponds to the area surrounded by the insulating layers 1212 and 1213 and the insulating layers 1221 and 1222. That is, the central portion of the lower electrode E12, which overlaps the opening OP2, is exposed from the insulating layer 12. The corners of the opening OP2 are rounded (or to have R (radius)). Note that the corners of the opening OP2 may not be rounded or may intersect at right angles. When viewed in plan view, the size (or area) of the opening OP3 is less than or equal to the size (or area) of the conductive layer CDL3 and is larger than or equal to the size (or area) of the reflective layer RL3. Note that the size (or area) of the opening OP3 may be larger than the size (or area) of the conductive layer CDL3. The size (or area) of the opening OP3 may be less than the size (or area) of the reflective layer RL3. The opening OP3 corresponds to the area surrounded by the insulating layers 1213 and 1214 and the insulating layers 1221 and 1222. That is, the central portion of the lower electrode E13, which overlaps the opening OP3, is exposed from the insulating layer 12. The corners of the opening OP3 are rounded (or to have R (radius)). The corners of the opening OP3 may not be rounded but may intersect at right angles.

In the example shown in FIG. 2, the insulating layer 12 covers the peripheral portion of each of the lower electrode E11 to E13. The insulating layer 1221 overlaps an end portion of the lower electrode E11, on an opposite side to the tip of the arrow in the second direction Y, an end portion of the lower electrode E12, on an opposite side to the tip of the arrow in the second direction Y, and an end portion of the lower electrode E13, on an opposite side to the tip of the arrow in the second direction Y. The insulating layer 1222 overlaps an end portion of the lower electrode E11, on a side of the tip of the arrow in the second direction Y, an end portion of the lower electrode E12, on a side of the tip of the arrow in the second direction Y, and an end portion of the lower electrode E13, on a side of the tip of the arrow in the second direction Y. The insulating layer 1211 overlaps an end portion of the lower electrode E11, on an opposite side to the tip of the arrow along the first direction X. The insulating layer 1212 overlaps an end portion of the lower electrode E11 on the tip of the arrow in the second direction Y, and an end portion of the lower electrode E12 on an opposite side to the tip of the arrow in the first direction X. The insulating layer 1213 overlaps an end portion of the lower electrode E12 on the tip of the arrow in the direction X, and overlaps an end portion of the lower electrode E13 on an opposite side to the tip of the arrow in the first direction X. The insulating layer 1214 overlaps an end portion of the lower electrode E13 on the side of tip of the arrow in the first direction X.

Here, the outline of the sub-pixel SP is equivalent to the outline of the lower electrode E1, for example. In other words, the sub-pixel SP1, the sub-pixel SP2 and the sub-pixel SP3, which constitute one pixel PX, are formed into a rectangular shape (or quadrangular). The sub-pixel SP1 is formed into an approximately rectangular shape extending along the second direction Y, the sub-pixel SP2 is formed into an approximately rectangular shape extending in the second direction Y, and the sub-pixel SP3 is formed into an approximately rectangular shape extending in the second direction Y. The sub-pixels SP1, SP2 and SP3 are aligned along the first direction X. The sub-pixels SP aligned adjacent to each other along the first direction X emit colors different from each other. Note that the emission colors of the adjacent sub-pixels SP may be the same as each other. The width of the sub-pixel SP1 along the first direction X, the width of the sub-pixel SP2 along in the first direction X, and the width of the sub-pixel SP3 along the first direction X are the same as each other. Note that the width of the sub-pixel SP1 along the first direction X, the width of the sub-pixel SP2 along the first direction X, the width of the sub-pixel SP3 along the first direction X may be different from each other. The width of the sub-pixel SP1 along the second direction Y, the width of the sub-pixel SP2 along the second direction Y, and the width of the sub-pixel SP3 along the second direction Y are the same as each other. Note that the width of the sub-pixel SP1 along the second direction Y, the width of the sub-pixel SP2 along in the second direction Y, and the width of the sub-pixel SP3 along the second direction Y may be different from each other. The area of the sub-pixel SP1, the area of the sub-pixel SP2 and the area of the sub-pixel SP3 3 are the same as each other. Note that the area of the sub-pixel SP1, the area of the sub-pixel SP2 and the area of the sub-pixel SP3 may be different from each other. The outline of the sub-pixels may be defined by the outline of the light-emitting area of the display element. The expressions “same”, “identical” and “equivalent” may cover situations where not only the physical quantity, material, or configuration (structure) of a plurality of subject objects, spaces, or areas and the like are exactly the same as each other, but also slightly different to the extent that they may be regarded as being substantially the same as each other.

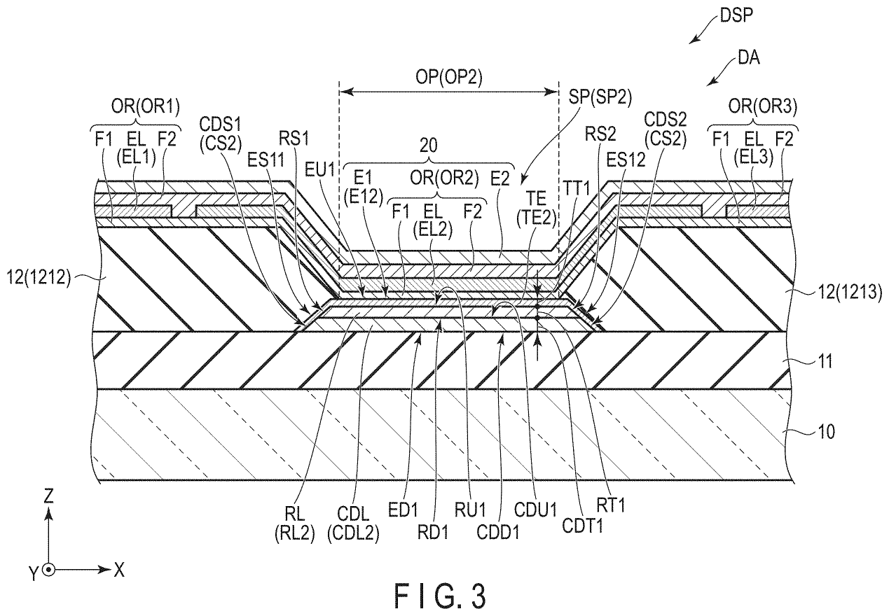

FIG. 3 is a cross-sectional view showing a configuration example of the display element 20 according to this embodiment. Note that FIG. 3 illustrates only the configuration necessary for explanation.

The display device DSP includes a base 10, an insulating layer 11, an insulating layer 12 (1212 and 1213), a display element 20 and an organic layer OR.

The display element 20 includes a lower electrode El (E12), an organic layer OR (OR2) and an upper electrode E2. The lower electrode E1 (E12) includes a conductive layer CDL (CDL2), a reflective layer RL (RL2) and a transparent electrode TE (TE2). Note that the lower electrode E1 may include a conductive layer CDL and a reflective layer RL. Further, the lower electrode E1 may as well include a reflective layer RL. The organic layers OR (OR1, OR2 and OR3) includes a functional layer F1, a light-emitting layer EL (EL1, EL2 and EL3) and a functional layer F2. The functional layers F1 and F2 include, for example, a hole injection layer, a hole transport layer, a hole block layer, an electron injection layer, an electron transport layer and an electron block layer. The functional layers F1 and F2 may not include at least one of the hole injection layer, hole transport layer, hole block layer, electron injection layer, electron transport layer and electron block layer. The functional layers F1 and F2 may as well include a layer(s) other than the hole injection layer, hole transport layer, hole block layer, electron injection layer, electron transport layer and electron block layer. Each of the functional layers F1 and F2 is not limited to a single layer, but may as well be a stacked body in which multiple functional layers are stacked. Further, at least one of the functional layers F1 and F2 may be omitted.

The insulating layer 11 is disposed on the base 10. The insulating layer 11 is equivalent to the base layer of the display element 20 and is, for example, an organic insulating layer. The pixel switch 2 and the like, of the pixel circuit 1 shown in FIG. 1 are disposed on the base 10 and are covered by an insulating layer, for example, the insulating layer 11, which is omitted from the figure. The insulating layer 11 may be formed from a single layer or multiple layers. Further, some other layer(s) may be disposed between the base 10 and the insulating layer 11.

The lower electrode E1 is disposed on the insulating layer 11. In the example shown in FIG. 3, the lower electrode E1 includes a lower electrode E12. The lower electrode E12 is disposed above the insulating layer 11. Although not shown in the figure, the lower electrode E1 is electrically connected to the switching element via a contact hole formed in the insulating layer 11. For example, although not shown, the lower electrode E12 is electrically connected to the switching element via the contact hole formed in the insulating layer 11. Note that between the lower electrode E1 and the insulating layer 11, some other layer(s) may be disposed. For example, between the lower electrode E12 and the insulating layer 11, some other layer(s) may be disposed.

In the example shown in FIG. 3, the lower electrode E1 comprises a conductive layer CDL, a reflective layer RL and a transparent electrode TE, which are stacked in the listed order. Not that the lower electrode E1 may be constituted by a conductive layer CDL and a reflective layer RL stacked in the listed order. The lower electrode E1 may as well be constituted by the reflective layer RL. The conductive layer CDL is disposed on the insulating layer 11. The conductive layer CDL is made of a metal material which has good electrical contact with the transparent electrode TE (and the switching element), for example, titanium or a metal material containing titanium (a titanium alloy). Note that as long as the conductive layer CDL has good electrical contact with the transparent electrode TE, it may be formed of a metal material other than titanium or a metal material containing titanium, that is, for example, TiN, Ta, TaN, Mo, W, Cr or the like. The conductive layer CDL is electrically connected to the switching element via the contact hole formed in the insulating layer 11. For example, although not shown in the figure, the conductive layer CDL is electrically connected to the switching element via the contact hole formed in the insulating layer 11. The conductive layer CDL includes a conductive layer CDL2. The reflective layer RL is disposed on the conductive layer CDL. The reflective layer RL is formed of a metal material that has high reflectivity and can be micro-processed by dry etching, and the like, for example, aluminum (Al), Al—Ni, Al—Ni—La, or a metal material containing aluminum (Al alloy). Note that the reflective layer RL may be, as long as it has high reflectivity and can be micromachined by dry etching or the like, made of any metal material other than aluminum (Al), Al—Ni, Al—Ni—La or a metal material containing aluminum. Lanthanum (La) has the effect of suppressing hillocks that may occur on the surface of the reflective layer RL. Therefore, when heat resistance is required, La may be added to the reflective layer RL. The reflective layer RL includes a reflective layer RL2. The transparent electrode TE is disposed on the reflective layer RL and the conductive layer CDL, to cover the reflective layer RL and the conductive layer CDL. For example, the transparent electrode TE covers at least the reflection layer RL so as not to expose the reflection layer RL. The transparent electrode TE is formed from a transparent electrode with a large band gap, for example, indium tin oxide (ITO). The transparent electrode TE includes a transparent electrode TE2.

For example, the lower electrode E12 comprises a conductive layer CDL2, a reflective layer RL2 and a transparent electrode TE2 stacked in the listed order. The cross-section of the lower electrode E12 has a tapered shape in the X-Z plane. The cross-section of the lower electrode E12 has a tapered shape in the X-Z plane. The cross-section of the lower electrode E12 is formed into a trapezoidal shape including, in the X-Z plane, an upper surface (or upper bottom) EU1 located on the side of the tip of the arrow in the third direction Z, a lower surface (or lower bottom) ED1 located on the opposite side to the upper bottom EU1 in the third direction Z, an end portion (a side portion, side portion or inclined surface) ES11 located on the opposite side of the tip of the arrow in the first direction X, and an end portion (a side portion, side surface or inclined surface) ES12 located on the opposite side to the end portion (a side portion, side portion or inclined surface) ES11 in the first direction X. The side portion ES11 is formed into an inclined surface from the tip side of the arrow in the first direction X (inner side) to the side opposite the tip of the arrow in the first direction X (outer side), that is, from the upper side towards the lower side in the third direction. In other words, the side ES11 is an inclined surface that expands to the opposite side to the tip of the arrow in the first direction X, towards the lower side along the third direction Z. The side ES12 is formed into an inclined surface from an opposite side (inner side) to the tip side (outer side) of the arrow in the first direction X, that is, from the upper side to the lower side in the third direction. In other words, the side portion ES12 is an inclined surface which expands to the tip side of the arrow in the first direction X towards the lower side in the third direction Z. The side portion ES11 is connected to the end portion of the lower bottom RD1, located on an opposite side to the tip of the arrow in the first direction X, and the end portion of the upper bottom EU1, located on an opposite side to the tip of the arrow in the first direction X. The side portion ES12 is connected to an end portion of the upper bottom EU1, opposite to the end to which the side portion ES11 is connected, and an end portion of the lower bottom ED1, opposite to the end to which the side portion ES11 is connected. The upper bottom EU1 is covered by an organic layer OR2. The side portion ES11 is covered by an insulating layer 12, for example, the insulating layer 1212. The side portion ES12 is covered by an insulating layer 12, for example, the insulating layer 1213. The width of the upper bottom EU1 in the first direction X is greater than or equal to the width of the opening OP2 in the first direction X. Note that the width of the upper bottom EU1 in the first direction X may be less than the width of the opening OP2 in the first direction X. As the process of forming the lower electrode E12, two processes of photoetching may be required for forming the conductive layer CDL2 and the reflective layer RL2 and the transparent electrode TE2, respectively. For example, in the process of formation of the lower electrode E12, the conductive layer CDL2 and the reflective layer RL2 are etched at one time by a forward taper manner.

The conductive layer CDL2 is disposed on the insulating layer 11. The conductive layer CDL2 is electrically connected to the switching element via the contact hole formed in the insulating layer 11. For example, although not shown in the figure, the conductive layer CDL2 is electrically connected to the switching element via the contact hole formed in the insulating layer 11. The cross-section of the conductive layer CDL2 has a tapered shape in the X-Z plane. The cross-section of the conductive layer CDL2 is formed into a trapezoidal shape including, in the Z-Y plane, an upper surface (or upper bottom) CDU1 located on the side of the tip of the arrow in the third direction Z, a lower surface (or lower bottom) CDD1 located on the opposite side to the upper bottom CDU1 in the third direction Z, an end portion (a side portion, side portion or inclined surface) CDS1 located on the opposite side of the tip of the arrow in the first direction X, and an end portion (a side portion, side surface or inclined surface) CDS2 located on the opposite side to the end portion (side portion, side portion or inclined surface) CDS1 in the first direction X. The side portion CDS1 is formed into an inclined surface from the tip side of the arrow in the first direction X (inner side) to the side opposite the tip of the arrow in the first direction X (outer side), that is, from the upper side towards the lower side in the third direction. In other words, the side CDS1 is an inclined surface that expands to the opposite side to the tip of the arrow in the first direction X, towards the lower side along the third direction Z. The side portion CDS2 is formed into an inclined surface from an opposite side (inner side) to the tip side of the arrow in the first direction X to the tip side (outer side) of the arrow in the first direction X, that is, from the upper side to the lower side in the third direction. In other words, the side portion CDS2 is an inclined surface which expands to the tip side of the arrow in the first direction X towards the lower side in the third direction Z. The end portions CDS1 and CDS2 are equivalent to a contact surface CS2. The side portion CDS1 is connected to the end portion of the upper bottom CDU1, located on an opposite side to the tip of the arrow in the first direction X, and the end portion of the lower bottom CDD1, located on an opposite side to the tip of the arrow in the first direction X. The side portion ES12 is connected to an end portion of the upper bottom CDU1, opposite to the end to which the side portion CDS1 is connected, and an end portion of the lower bottom CDD1, opposite to the end to which the side portion CDS1 is connected. The lower bottom CDD1 is located on the insulating layer 11. The side portions CDS1 and CDS2 are covered by the transparent electrode TE2. A thickness CDT1 of the conductive layer CDL2 is greater than or equal to a thickness RT1 of the reflective layer RL2. For example, the thickness CDT1 of the conductive layer CDL2 is 100 nm (nanometer) or less.

The reflective layer RL2 is disposed on the conductive layer CDL2. The cross-section of the reflective layer RL2 has a tapered shape in the X-Z plane. The cross-section of the reflective layer RL2 is formed into a trapezoidal shape including, in the X-Z plane, an upper surface (or upper bottom) RU1 located on the tip side of the arrow in the third direction Z, a lower surface (or lower bottom) RD1 located on the opposite side to the upper bottom RU1 in the third direction Z, an end portion (a side portion, side surface or inclined surface) RS1 located on the opposite side of the tip of the arrow in the first direction X, and an end portion (a side portion, side surface or inclined surface) RS2 located on the opposite side to the inclined surface RS1 in the first direction X. The end portion RS1 is formed into an inclined surface from the tip side (inner side) of the arrow in the first direction X to an opposite side (outer side) to the tip side of the arrow in the first direction X, that is, from the upper side to the lower side in the third direction. In other words, the side portion RS1 is an inclined surface which expands to an opposite side (outer side) to the tip of the arrow in the first direction X towards the lower side in the third direction Z. For example, the side portion RS1 is formed into an inclined surface that is continuous to the side portion CDS1 in the X-Y plane. In other words, the side portion CDS1 is located on an outer side further from the side portion RS1, that is, for example, on an opposite side to the tip of the arrow in the first direction X. For example, the side portion RS1 and the side portion CDS1 are formed at one time in forward tapering etching manner in the X-Y plane. The side portion RS2 is formed into an inclined surface from an opposite side (inner side) to the tip of the arrow in the first direction X towards the tip side (outer side) of the arrow in the first direction X from the upper side to the lower side in the third direction Z. In other words, the side portion RS2 is formed into an inclined surface which expands toward the tip side (outer side) of the arrow in the first direction X from the opposite side (inner side) to the tip of the arrow in the first direction X. In other words, the side portion RS2 is an inclined surface which expands to the tip side of the arrow in the first direction X toward the lower side in the third direction 3. For example, the side portion RS2 is formed into an inclined surface that is continuous to the side portion CDS2 in the X-Y plane. In other words, the side portion CDS2 is located on a further outer side of the side portion RS2, that is, for example, on the opposite side to the tip of the arrow in the first direction X. For example, the side portion RS2 and the side portion CDS2 are formed at once by forward taper etching in the X-Y plane. The side portion RS1 is connected to the end portion of the upper bottom RU1, which is located on an opposite side to the tip of the arrow in the first direction X and the end portion of the lower bottom RD1, which is located on an opposite side to the tip of the arrow in the first direction X. The side portion RS2 is connected to the end portion of the upper bottom RU1, on an opposite side to the end to which the side portion RS1 is connected, and the end portion of the lower bottom RD1, which is located on an opposite side to the end to which the side portion RS1 is connected. The lower bottom RD1 is located on the upper bottom CDU1 of the conductive layer CDL2. The width of the lower bottom RD1 along the first direction X is the same as the width of the upper bottom CDU1 of the conductive layer CDL2 along the first direction X. Note that the width of the lower bottom RD1 along the first direction X may be less than the width of the upper bottom CDU1 of the conductive layer CDL2 along the first direction X. The width of the upper bottom RU1 along the first direction X is greater than or equal to, for example, the width of the opening OP2 along the first direction X. The width of the upper bottom RU1 along the first direction X may be, for example, less than the width of the opening OP2 along the first direction X. The upper bottom RU1, the side portion RS1 and the side portion RS2 are covered by the transparent electrode TE2. For example, in the case where the reflective layer RL2 is Al or an Al alloy and the transparent electrode TE is ITO, it is difficult to electrically connect the transparent electrode TE to the reflective layer RL2 because Alx is formed at the interface of the reflective layer RL2. The thickness RT1 of the reflective layer RL2 is less than or equal to the thickness CDT1 of the conductive layer CDL2. Further, the thickness RT1 of the reflective layer RL2 is greater than the thickness TT1 of the transparent electrode TE2. For example, the thickness RT1 of the reflective layer RL2 is 50 to 100 nm. For example, the thickness TT2 of the transparent electrode TE2 is 5 to 10 nm.

In the patterning process after the formation of the lower electrode E1, when the lower electrode E1 of aluminum and ITO is exposed to an atmosphere of alkaline liquid (for example, stripping solution, developing solution or the like) in a stripping process or the like, a mutual corrosion reaction (galvanic corrosion reaction) between aluminum and ITO may occur. When the galvanic corrosion reaction occurs, degradation of pixels PX, rise in applied voltage and degradation of the lower electrode E1 over time may occur. In the lower electrode E1 of the display element 20 shown in FIG. 3, the reflection layer RL is covered by the transparent electrode TE, and thus the reflective layer RL and the transparent electrode TE are prevented from being exposed to an alkaline liquid atmosphere at the same time. In this manner, the occurrence of galvanic corrosion reactions can be prevented in the display element 20 shown in FIG. 3.

In the example shown in FIG. 3, the insulating layer 12 is located on the insulating layer 11 and the lower electrode E1. The insulating layer 12 may be formed from a single layer or in multiple layers. The insulating layer 12 includes the insulating layers 1212 and 1213. For example, the insulating layer 1212 covers the insulating layer 11 and the side portion ES11 of the lower electrode E12. The insulating layer 1212 covers the transparent electrode TE2 which covers the side portion RS1 of the reflective layer RL2 and the side portion CDS1 of the conductive layer CDL2. The insulating layer 1213 covers the insulating layer 11 and the end portion ES12 of the lower electrode E12. The insulating layer 1213 covers the transparent layer TE2 which covers the side portion RS2 of the reflective layer RL2 and the side portion CDS2 of the conductive layer CDL2.

The organic layer OR covers the lower electrode E1 and the insulating layer 12. The organic layer OR is constituted by a functional layer F1, a light-emitting layer EL and a functional layer F2 stacked in the order listed. In the example shown in FIG. 3, the organic layer OR includes organic layers OR1, OR2 and OR3. For example, the organic layer OR2 covers the lower electrode E12, the insulating layer 1212 and the insulating layer 1213. The organic layer OR2 comprises a functional layer F1, a light-emitting layer EL2 and a functional layer F2, which are stacked in the order listed. The organic layer OR1 is located on the opposite side to the organic layer OR2 with respect to the tip of the arrow in the first direction X. The organic layer OR1 covers the insulating layer 1212. The organic layer OR1 is constituted by a functional layer F1, a light-emitting layer EL1 and a functional layer F2, which are stacked in the order listed. The organic layer OR3 is located on the tip side of the organic layer OR2 with respect to the arrow in the first direction X. The organic layer OR3 covers the insulating layer 1213. The organic layer OR3 comprises a functional layer F1, a light-emitting layer EL3 and a functional layer F2, which are stacked in the order listed. The functional layer F1 covers the insulating layer 1212, the transparent electrode TE2 and insulating layer 1213. The light-emitting layers EL1, EL2 and EL3 are arranged in the order listed so as to be spaced apart from each other along the first direction X. The light-emitting layer EL2 is disposed to be spaced apart on the tip side of the light emitting layer EL1 with respect to the arrow in the first direction X. The light-emitting layer EL3 is disposed to be spaced apart on the tip side of the light emitting layer EL2 with respect to the arrow in the first direction X. The light-emitting layers EL1, EL2 and EL3 are disposed on the functional layer F1. The light-emitting layers EL1 to EL3 are light-emitting layers of different colors, for example. The light-emitting layer EL1 is, for example, a red light-emitting layer, the light-emitting layer EL2 is, for example, a green light-emitting layer, and the light-emitting layer EL3 is, for example, a blue light-emitting layer. Note that the light-emitting layer EL1 may be, for example, a green or blue light-emitting layer. The light-emitting layer EL2 may be, for example, a red or blue light-emitting layer. The light-emitting layer EL3 may be, for example, a red or green light-emitting layer. The light-emitting layers EL1 through EL3 may be light-emitting layers of the same color, for example, white. The functional layer F2 covers the light-emitting layers EL1, EL2 and EL3.

The upper electrode E2 is disposed on the organic layer OR. In the example shown in FIG. 3, the upper electrode E2 is disposed on the organic layer OR1, organic layer OR2 and organic layer OR3. For example, the upper electrode E2 is disposed on the functional layer F2. The upper electrode E2 is made of MgAg or a metal material containing MgAg. Note that the upper electrode E2 may be made of, for example, a transparent conductive material such as indium tin oxide (ITO) or indium zinc oxide (IZO). Further, the upper electrode E2 is an electrode commonly disposed for a plurality of sub-pixels SP or a plurality of display elements 20, and may be referred to as a common electrode, a counter electrode, a negative electrode or a cathode. Note that the upper electrode E2 may be covered by a transparent protective layer (including at least one of an inorganic insulating layer and an organic insulating layer). The upper electrode E2 may be constituted by a single layer or as a stacked layer body. Note that the upper electrode E2 may be electrically connected to the feeding line FL located in the display area DA shown in FIG. 1.

In the example shown in FIG. 3, the display device DSP comprises a reflective layer (for example, Al or Al alloy) RL2 and a transparent electrode (for example, ITO) TE2 disposed on top of the reflective layer, and with this structure, it is possible to optimize the work function for hole injection into the organic layer OR2 and to prevent the creation of unevenness due to hillocks on the surface of the reflective layer RL2.

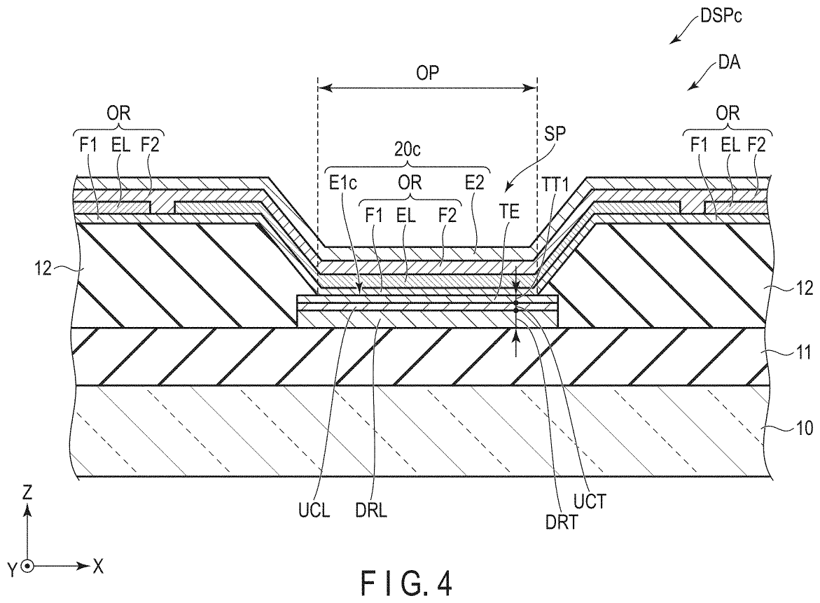

FIG. 4 is a cross-sectional view showing a configuration example of the display element 20c according to a comparative example. In the display device DSP shown in FIG. 4, parts that are identical to those of the display device DSP shown in FIG. 3 are designated by the same reference symbols, and the detailed explanations thereof will be omitted. The parts different from those described above will be mainly explained.

The display device DSP of the comparative example includes a base 10, an insulating layer 11, an insulating layer 12, a display element 20c and an organic layer OR. The display element 20c includes a lower electrode Elc, an organic layer OR and an upper electrode E2. The lower electrode Elc includes a reflective layer DRL, a conductive layer UCL and a transparent electrode TE.

In the example shown in FIG. 4, the lower electrode Elc comprises a reflective layer DRL, a conductive layer UCL and a transparent electrode TE, which are stacked in the order listed. The reflective layer DRL is placed on the insulating layer 11. Between the reflective layer DRL and the insulating layer 11, some other layer may be disposed. The reflective layer DRL is made of a metal material which has high reflectivity and can be micromachined by dry etching or the like, that is, for example, aluminum (Al), Al—Ni, Al—Ni—La or a metal material containing aluminum (Al alloy). As long as it has high reflectivity and can be micromachined by dry etching, metal materials other than aluminum (Al), Al—Ni, Al—Ni—La or a metal material containing aluminum (Al alloy) may be used for the reflective layer DRL. The reflective layer DRL is electrically connected to the switching device via a contact hole formed in the insulating layer 11. For example, although not shown in the figure, the reflective layer DRL is electrically connected to the switching element via the contact hole formed in the insulating layer 11. The conductive layer UCL is disposed on the reflective layer DRL. The conductive layer UCL is formed of a metal material that has good electrical contact with the transparent electrode TE, that is, for example, titanium (Ti) or a metal material containing titanium. Note that as long as it has good electrical contact with the transparent electrode TE, metal materials other than titanium or a titanium-containing metallic material, that is, for example, TiN, Ta, TaN, Mo, W, Cr or the like may be used to form the conductive layer UCL. The transparent electrode TE is disposed on the conductive layer UCL. The transparent electrode TE is formed from a transparent electrode with a large band gap, for example, indium tin oxide (ITO).

The cross-section of the lower electrode Elc is, in the X-Z plane, formed into a rectangular shape whose length along the first direction X is greater than the length along the third direction Z. The cross-section of the reflective layer DRL is, in the X-Z plane, formed into a rectangular shape whose length along the first direction X is greater the length along the third direction Z. The cross-section of the conductive layer UCL is, in the X-Z plane, formed into a rectangular shape whose length along the first direction X is greater than the length in the third direction Z. The cross-section of the transparent electrode TE is, in the X-Z plane, formed into a rectangular shape whose length along the first direction X is greater than the length along the third direction Z.

Both end portions of the lower electrode E1c along the first direction X are covered by the insulating layer 12. Both end portions of the reflective layer DRL along the first direction X are covered by the insulating layer 12. Both end portions of the conductive layer UCL along the first direction X are covered by the insulating layer 12. Both end portions of the transparent electrode TE along the first direction X are covered by the insulating layer 12. The width of the reflective layer DRL along the first direction X, the width of the conductive layer UCL along the first direction X and the width of the transparent electrode TE along the first direction X are the same as each other. The width of the reflective layer DRL along the first direction X is, for example, greater than or equal to the width of the opening OP along the first direction X. Note that the width of the reflective layer DRL along the first direction X may be less than the width of the opening OP along the first direction X. The thickness UCT of the conductive layer UCL is, for example, less than the thickness DRT of the reflective layer DRL.

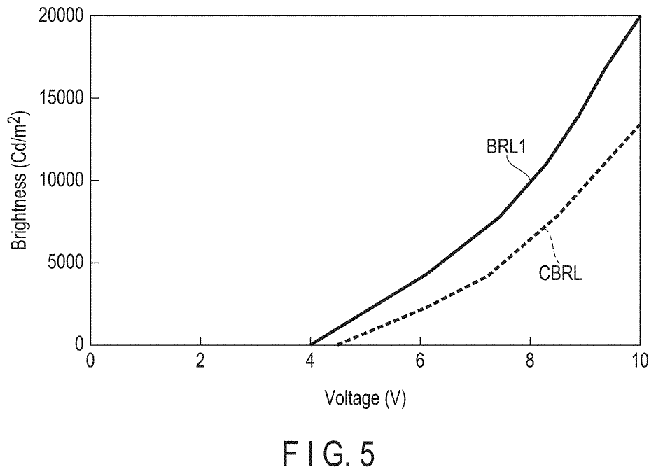

FIG. 5 is a schematic diagram showing an example of a brightness-voltage curve. In FIG. 5, the horizontal axis indicates voltage (V) and the vertical axis indicates brightness (Cd/m2). FIG. 5 illustrates a brightness-voltage curve BRL1 corresponding to the display device DSP of the embodiment shown in FIG. 3 and a brightness voltage curve CBRL corresponding to the display device DSPc of the comparative example shown in FIG. 4.

In the example shown in FIG. 5, the brightness-voltage curve BRL1 is about 30% higher than the brightness voltage curve CBRL. In other words, the brightness of the display device DSP of the embodiment shown in FIG. 3 can be improved by about 30% as compared to the brightness of the display device DSPc of the comparative example shown in FIG. 4. The reason why the brightness of the display device DSPc shown in

FIG. 3 can be improved as compared to that of the display device DSPc shown in FIG. 4 is as follows. That is, in the display device DSPc of the comparative example shown in FIG. 4, the reflective layer UCL of low reflectivity is disposed on the reflective layer DRL of high reflectivity, whereas in the display device DSP of the embodiment shown in FIG. 3, the transparent electrode TE2 is disposed on the reflective layer RL2 with high reflectivity. The display device DSP of this embodiment, compared with the display device DSPc of the comparative example, can reduce the drive voltage to achieve the predetermined brightness, and therefore the life of the display element 20 can be improved. Further, the display device DSP according to this embodiment has such a structure that the lower electrode E1 is configured so that the reflection layer RL1 is covered by the transparent electrode TE1, and therefore damage due to corrosion of the lower electrode E1 can be reduced. Therefore, the display device DSP of this embodiment can achieve lower drive voltage as well.

According to this embodiment, the display device DSP comprises a base 10, an insulating layer 11, an insulating layer 12 and a display element 20. The display element 20 includes a lower electrode E1, an organic layer OR and an upper electrode E2. The lower electrode E1 includes a conductive layer CDL, a reflective layer RL and a transparent electrode TE. The organic layer OR includes a functional layer F1, a light-emitting layer EL and a functional layer F2. The insulating layer 11 is disposed on the base 10. The lower electrode E1 is disposed on the insulating layer 11. The lower electrode E1 comprises a conductive layer CDL, a reflective layer RL and a transparent electrode TE, which are stacked in the order listed. The conductive layer CDL is disposed on the insulating layer 11. The reflective layer RL is disposed on the conductive layer CDL. The transparent electrode TE covers the reflective layer RL and the conductive layer CDL. In the lower electrode E1 of the display device DSP in this embodiment, the reflection layer RL is completely covered by the transparent electrode TE, which prevents the reflective layer RL and the transparent electrode TE from being exposed to an alkaline liquid atmosphere at the same time. Therefore, the display device DSP of this embodiment can prevent the occurrence of galvanic corrosion reactions. That is, the display device DSP can prevent degradation of the pixels PX, rise in applied voltage and degradation over time. The display device DSP can improve the brightness. Therefore, the display device DSP can improve the display quality.

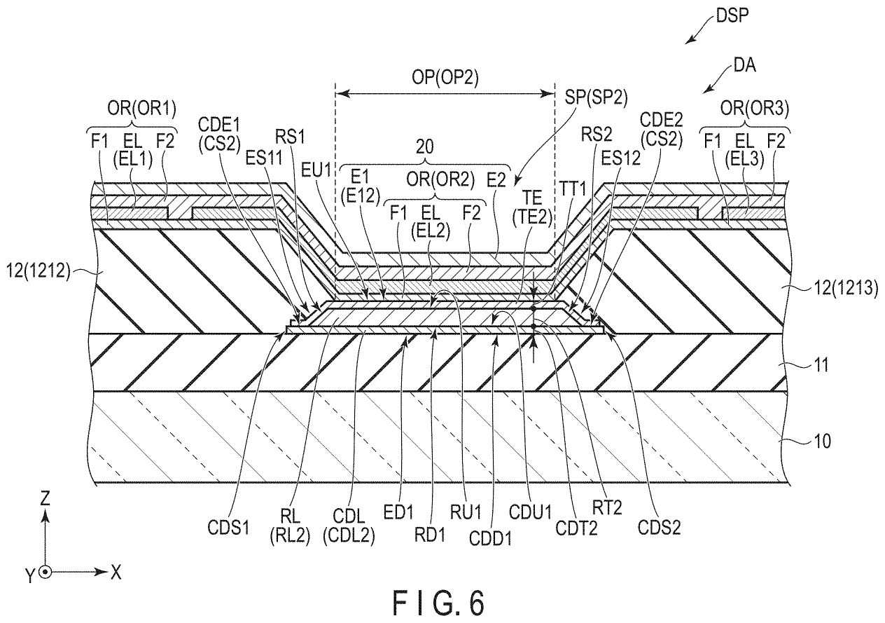

Next, modified examples of the first embodiment and embodiments other than the first embodiment will be described with reference to FIGS. 6, 7, 8, 9, 10, 11, 12, 13 and 14. In the modified examples of the first embodiment and embodiments other than the first embodiment described below, parts identical to those described above are marked with the same reference symbols, and detailed descriptions thereof will be omitted. Parts different from those described above will be mainly explained in detail. Note that advantageous effects similar to those of the embodiments described above can be obtained in the modified examples of the first embodiment and other embodiments than the first embodiment as well.

### Modified Example 1

The display device DSP of Modified Example 1 is different from the display device DSP of the aforementioned embodiment in the configuration of the lower electrode E1.

FIG. 6 is a cross-sectional view showing a configuration example of a display device 20 according to Modified Example 1. FIG. 6 shows only the configuration necessary for explanation. In the example shown in FIG. 6, the cross-section of the lower electrode E12 is formed into, in the X-Z plane, an approximately trapezoidal shape including an upper surface EU1, a lower surface ED1, an end portion ES11 and an end portion ES12.

In the example shown in FIG. 6, the conductive layer CDL2 is formed into a plate shape. The cross-section of the conductive layer CDL2 is formed into, in the X-Z plane, a rectangular shape including an upper surface CDU1, a lower surface CDD1, an end portion CDS1 and an end portion CDS2. The cross-section of the conductive layer CDL2 is formed into a rectangular shape whose length along the first direction X is greater than the length along the third direction Z. The conductive layer CDL2 includes an upper surface CDE1 of the end portion CDS1 and an upper surface CDE2 of the end portion CDS2. The upper surface CDE1 is equivalent to the end portion of the upper surface CDU1 on a side opposite to the tip of the arrow in the first direction X. The upper surface CDE2 is equivalent to the end portion of the upper surface CDU1 on the tip side of the arrow along the first direction X. The upper surfaces CDE1 and CDE2 are equivalent to contact surface CS2. The upper surfaces CDE1 and CDE2 are covered by the transparent electrode TE2. In other words, the upper surfaces CDE1 and CDE2 are in contact with the transparent electrode TE2. On the upper surface CDU1 except for the upper surface CDE1 and CDE2, the reflective layer RL2 is provided. That is, the upper surfaces CDE1 and CDE2 are each located on an outer side from the reflective layer RL2. The upper surface CDE1 is located on an opposite side to the tip of the arrow in the first direction X, with respect to the reflective layer RL2. The upper surface CDE2 is located on the side of the tip of the arrow in the first direction X with respect to the reflective layer RL2. The end portions CDS1 and CDS2 each project outwards from the reflective layer RL2. The end portion CDS1 projects to an opposite side to the tip of the arrow along the first direction X with respect to the reflective layer RL2. The end portion CDS2 projects to the tip side of the arrow along the first direction X with respect to the reflective layer RL2. The width of the conductive layer CDL2 along the first direction X is, for example, greater than the width of the opening OP2 along the first direction X. Note that the width of the conductive layer CDL2 along the first direction X may be less than or equal to the width of the opening OP2 along the first direction X. The thickness CDT2 of the conductive layer CDL2 is greater than or equal to the thickness TT1 of the transparent electrode TE2.

In the example shown in FIG. 6, the reflective layer RL2 is disposed on the upper surface CDU1 except for the upper surfaces CDE1 and CDE2 of the conductive layer CDL2. The width of the reflective layer RL2 along the first direction X is less than the width of the conductive layer CDL2 along the first direction X. That is, the width of conductive layer CDL2 along the first direction X is greater than the width of the reflective layer RL2 along the first direction X. The side portions RS1 and RS2 are each disposed on an inner side with respect to the conductive layer CDL2. The side portion RS1 is retracted to the tip of the arrow along the first direction X with respect to the conductive layer CDL2. The side portion RS2 is retracted to the opposite side to the tip of the arrow along the first direction X with respect to the conductive layer CDL2. The thickness RT2 of the reflective layer RL2 is greater than the thickness CDT2 of the conductive layer CDL2.

In the example shown in FIG. 6, the insulating layer 1212 covers the side portion ES11 of the lower electrode E12. The insulating layer 1212 covers the transparent electrode TE2 which covers the side portion RS1 of the reflective layer RL2 and the upper surface CDE1, and the end portion CDS1 of the conductive layer CDL2. The insulating layer 1213 covers the side portion RS12 of the lower electrode E12. The insulating layer 1213 covers the side portion RS2 of the reflective layer RL2 and the upper surface CDE2, and the end portion CDS2 of the conductive layer CDL2.

In Modified Example 1 having such a configuration as described above, an advantageous effect similar to that of the first embodiment can be exhibited.

Additionally, in the display device DSP according to Modified Example 1, the width of the conductive layer CDL along the first direction X is greater than the width of the reflective layer RL along the first direction X, and therefore the contact properties between the conductive layer CDL and the transparent electrode TE can be improved.

### Modified Example 2

The display device DSP of Modified Example 2 is different from the display device DSP of the embodiment described above or that of the modified example thereof in the configuration of the lower electrode E1.

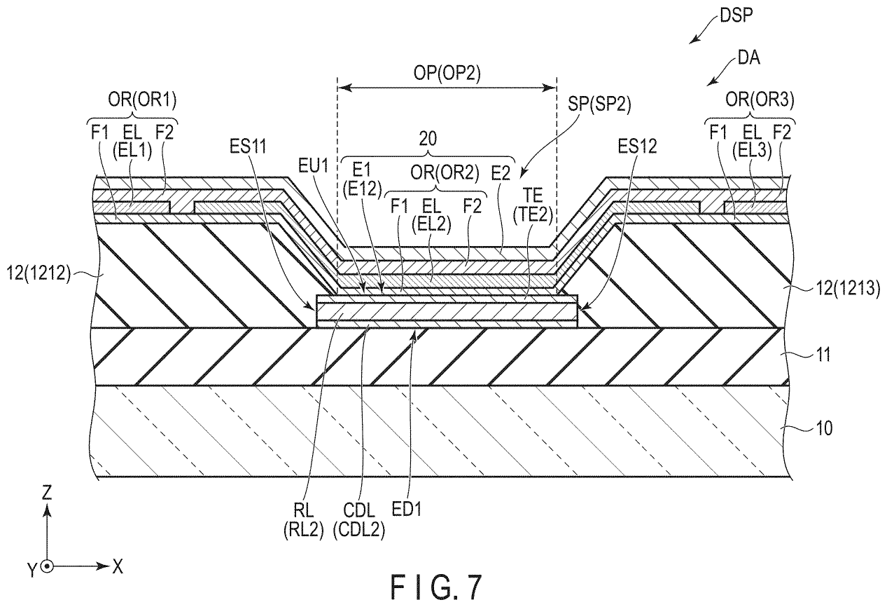

FIG. 7 is a cross-sectional view of a configuration example of a display device 20 according to Modified Example 2. FIG. 7 illustrates only the configuration necessary for explanation.

In the example shown in FIG. 7, the cross-section of the lower electrode E12 is formed into a rectangular shape, in the X-Z plane, including an upper surface EU1, a lower surface ED1, a side portion ES11 and a side portion ES12.

In the example shown in FIG. 7, the conductive layer CDL2 is formed into a plate shape. The cross-section of the conductive layer CDL2 is formed into a rectangular shape whose length along the first direction X is greater than the length along the third direction Z. The width of the conductive layer CDL2 along the first direction X is greater than or equal to the width of, for example, the opening OP2 along the first direction X. Note that the width of the conductive layer CDL2 along the first direction X may be less than the width of, for example, the opening OP2 along the first direction X.

In the example shown in FIG. 7, the reflective layer RL2 is directly contactable (or electrically contactable) with the transparent electrode TE and has a corrosion potential equivalent to that of the transparent electrode TE. That is, the reflective layer RL2 is formed of a material which does not generate a galvanic corrosion reaction, that is, for example, Al—Ni, Al—W alloy, Al—Mo alloy, Al—Ti alloy, Al—Ni—W, Al—Ni—Mo alloy or Al13 Ni—Ti alloy.

In the example shown in FIG. 7, the reflective layer RL2 is disposed on the conductive layer CDL2. The reflective layer RL2 is formed into a plate shape. The cross-section of the reflective layer RL2 is formed into a rectangular shape whose length along the first direction X is greater than the length along the third direction Z. The width of the reflective layer RL2 along the first direction X is greater than or equal to the width of, for example, the opening OP2 along the first direction X. Note that the width of the reflective layer RL2 along the first direction X may be less than the width of, for example, the opening OP2 along the first direction X. For example, the width of the reflective layer RL2 along the first direction X is the same as the width of the conductive layer CDL2 along the first direction X. Note that the width of the reflective layer RL2 along the first direction X may be different from the width of the conductive layer CDL2 along the first direction X.

In the example shown in FIG. 7, the reflective layer RL2 is formed of Al alloy, which can decrease the contact resistance between the transparent electrode (for example, ITO) TE2 and the reflective layer (for example, Al alloy) RL2. Therefore the conductive layer CDL2, the reflective layer RL2 and the transparent electrode TE2, of the lower electrode E12, can be processed together at once by a single photolithography process.

In the example shown in FIG. 7, the transparent electrode TE2 is disposed on the reflective layer RL2. The transparent electrode TE2 is formed into a plate shape. The cross-section of the transparent electrode TE2 is, in the X-Z plane, formed into a rectangular shape whose length along the first direction X is greater than the length along the third direction Z. The width of the transparent electrode TE2 along the first direction X is larger than or equal to the width of, for example, the opening OP2 along the first direction X. Note that the width of the transparent electrode TE2 along the first direction X may be less than the width of, for example, the opening OP2 along the first direction X. For example, the width of the transparent electrode TE2 along the first direction X is the same as the width of the reflective layer RL2 along the first direction X and the width of the conductive layer CDL2 along the first direction X. Note that the width of the transparent electrode TE2 along the first direction X may be different from the width of the reflective layer RL2 along the first direction X and the width of the conductive layer CDL2 along the first direction X.

In the example shown in FIG. 7, the insulating layer 1212 covers the side portion ES11 of the lower electrode E12. The insulating layer 1212 covers the end portion of the conductive layer CDL2, on an opposite side to the tip of the arrow along the first direction X, the end portion of the reflective layer RL2, on an opposite side to the tip of the arrow along the first direction X, and the end portion of the transparent electrode TE2, on an opposite side to the tip of the arrow along the first direction X. The insulating layer 1213 covers a side portion ES12 of the lower electrode E12. The insulating layer 1213 covers the end portion of the conductive layer CDL2, on the tip end side of the arrow along the first direction X, the end portion of the reflective layer RL2, on the tip end side of the arrow along the first direction X, and the end portion of the transparent electrode TE2, on the tip end side of the arrow along the first direction X.

In Modified Example 2 as well, advantageous effects similar to those of the first embodiment can be obtained.

### Modified Example 3

The display device DSP of Modified Example 3 is different from the display device DSP of each of the embodiment described above and the modified examples in the configuration of the lower electrode E1.

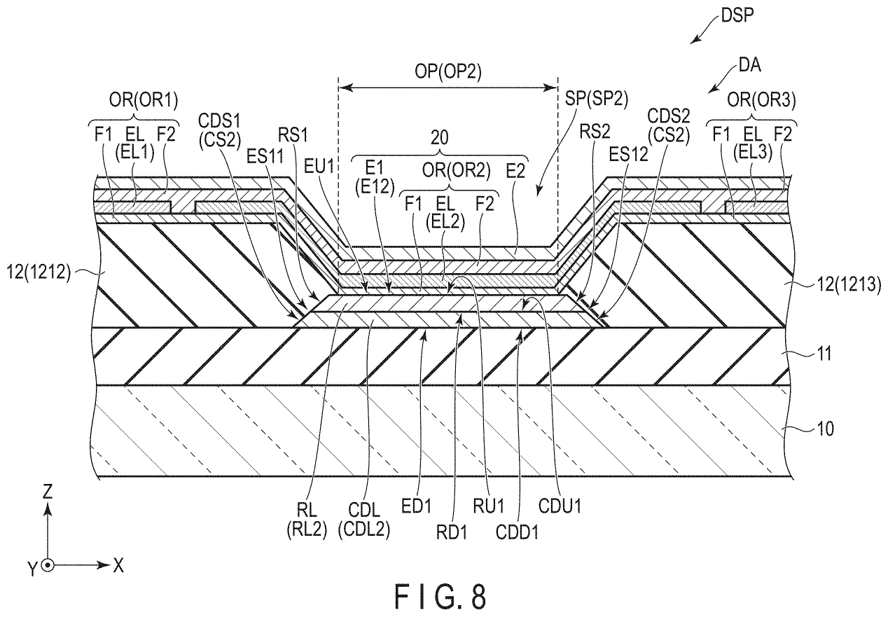

FIG. 8 is a cross-sectional view showing a configuration example of a display device 20 according to Modified Example 3.

In the example shown in FIG. 8, the lower electrode E12 comprises a conductive layer CDL2 and a reflective layer RL2, which are stacked in the order listed. The cross-section of the lower electrode E12 has a tapered shape in the X-Z plane. The cross-section of the lower electrode E12 is, in the X-Z plane, formed into a trapezoidal shape including an upper bottom EU1, a lower bottom ED1, a side portion ES11 and a side portion ES12. The cross-section of the lower electrode E12 may be, in the X-Z plane, formed into a rectangular shape whose length along the first direction X is greater than the length along the third direction Z.

In the example shown in FIG. 8, the cross-section of the conductive layer CDL2 is, in the X-Z plane, formed into a trapezoidal shape including an upper bottom CDU1, a lower bottom CDD1, a side portion CDS1 and a side portion CDS2. The cross-section of the conductive layer CDL2 may be, in the X-Z plane, formed into a rectangular shape whose length along the first direction X is greater than the length along the third direction Z. The width of the conductive layer CDL2 along the first direction X may be greater than or equal to the width of the opening OP2 along the first direction X, or less than the width of the opening OP2 along the first direction X. The side portion CDS1 is covered by the insulating layer 1212. The side portion CDS2 is covered with an insulating layer 1213.

In the example shown in FIG. 8, the cross-section of the reflective layer RL2 is, in the X-Z plane, formed into a trapezoidal shape including an upper bottom RU1, a lower bottom RD1, a side portion RS1 and a side portion RS2. Note that the cross-section of the reflective layer RL2 may be, in the X-Z plane, formed in a rectangular shape whose length along the first direction X is greater than the length along the third direction Z. The width of the reflective layer RL2 along the first direction X may be greater than or equal to the width of the opening OP2 along the first direction X, or less than the width of the opening OP2 along the first direction X. The side portion RS1 is covered by the insulating layer 1212. The side portion RS2 is covered by the insulating layer 1213.

In the example shown in FIG. 8, the insulating layer 1212 covers the side portion ES11 of the lower electrode E12. The insulating layer 1212 covers the side portion RS1 and the side portion CDS1. The insulating layer 1213 covers the side portion ES12 of the lower electrode E12. The insulating layer 1213 covers the side portion RS2 and the side portion CDS2.

In the example shown in FIG. 8, the functional layer Fl covers the insulating layer 1212, the reflective layer RL2 and the insulating layer 1213. In other words, the functional layer Fl covers the insulating layer 1212, the upper bottom RU1 and the insulating layer 1213.

In the example shown in FIG. 8, even the reflective layer (for example, Al or Al alloy) RL2 can be subjected to hole injection into the organic layer OR2 in terms of work function.

In Modified Example 3 as well, advantageous effects similar to those of the first embodiment can be obtained. In addition, the width of the reflective layer RL2 along the first direction X can be made greater than the width of the reflective layer RL2 in the first direction X of the first embodiment, and thus the aperture efficiency can be improved by increasing the width of the reflective layer RL2 along the first direction X. Further, as to the display device DSP of Modified Example 3, the number of processing steps in the formation process of the lower electrode E12 of the display device DSP of the first embodiment by one.

### Modified Example 4

The display device DSP of Modified Example 4 is different from the display device DSP of each of the embodiment and the modified examples thereof in the configuration of the organic layer OR.

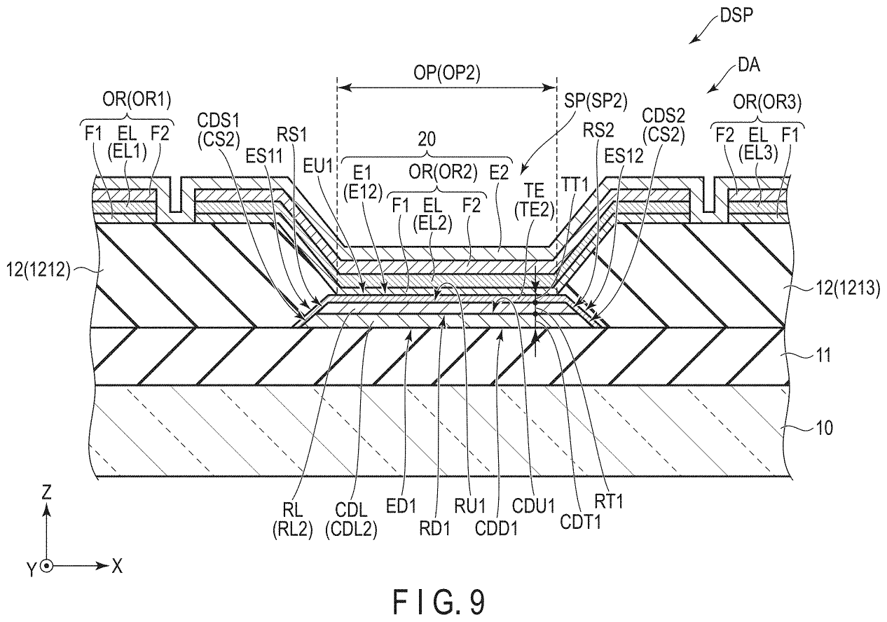

FIG. 9 is a cross-sectional view showing a configuration example of a display device 20 according to Modified Example 4. FIG. 9 illustrates only the configuration necessary for explanation.

In the example shown in FIG. 9, the organic layer OR1 and the organic layer OR2 are separated from each other along the first direction X with a groove penetrating to the insulating layer 1212 therebetween.

The organic layer OR2 and the organic layer OR3 are separated from each other along the first direction X with a groove penetrating to the insulating layer 1213 therebetween.

In the example shown in FIG. 9, the upper electrode E2 is disposed on the organic layer OR and the insulating layer 12. For example, the upper electrode E2 covers the organic layer OR1, the insulating layer 1212, the organic layer OR2, the insulating layer 1213 and the organic layer OR3. The upper electrode E2 covers, in the groove between the organic layer OR1 and the organic layer OR2, a side surface of the organic layer OR1, on the tip side of the arrow along the first direction X, a side surface of the organic layer OR2, on an opposite side to the tip of the arrow along the first direction X and an upper surface of the insulating layer 1212. The upper electrode E2 covers, in the groove between the organic layer OR2 and the organic layer OR3, a side surface of the organic layer OR2, on the tip side of the arrow along the first direction X, a side surface of the organic layer OR3, on an opposite side to the tip of the arrow along the first direction X and an upper surface of the insulating layer 1213.

In Modified Example 4 as well, advantageous effects similar to those of the first embodiment can be obtained.

### Modified Example 5

The display device DSP of Modified Example 5 is different from the display device DSP of each of the embodiment and the modified examples thereof in the configuration of the organic layer OR.

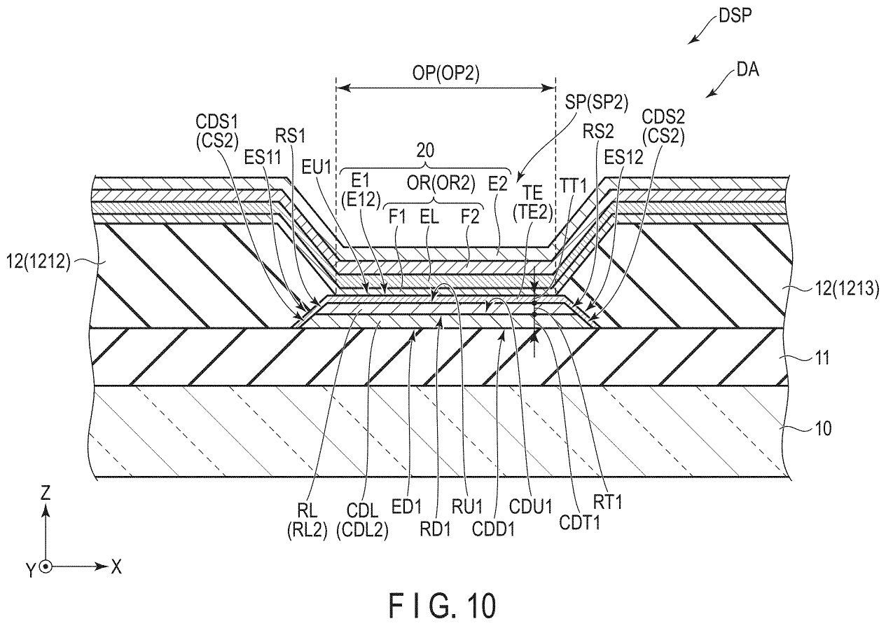

FIG. 10 is a cross-sectional view showing a configuration example of a display device 20 according to Modified Example 5. FIG. 10 illustrates only the configuration necessary for explanation.

In the example shown in FIG. 10, the organic layer OR covers the lower electrode E1, the insulating layer 1212 and the insulating layer 1213. The organic layer OR comprises a functional layer F1, a light-emitting layer EL and a functional layer F2, which are stacked in the order listed. The light-emitting layer EL is, for example, a white light-emitting layer.

In Modified Example 5 as well, advantageous effects similar to those of the first embodiment can be obtained.

### Second Embodiment

The display device DSP of the second embodiment is different from the display device DSP of each of the embodiment described above and the modified examples thereof in the configurations of the organic layer OR and the insulating layer 12.

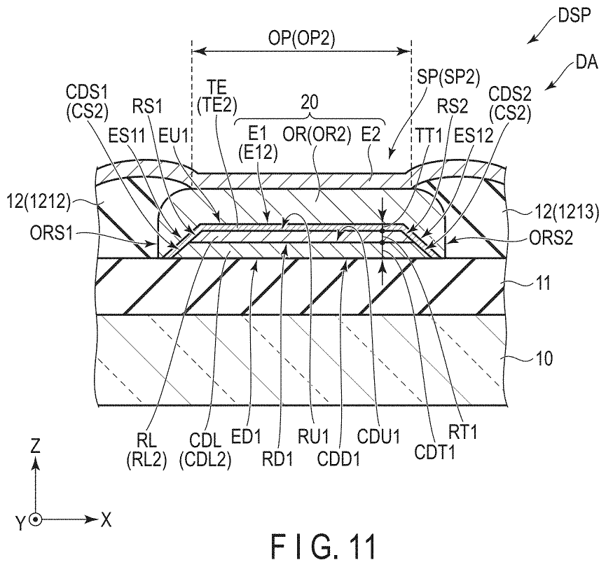

FIG. 11 is a cross-sectional view showing a configuration example of a display device 20 according to the second embodiment. FIG. 11 illustrates only the configuration necessary for explanation.

In the example shown in FIG. 11, the lower electrode E1 corresponds to the lower electrode E1 shown in FIG. 3.

In the example shown in FIG. 11, the cross-section of the organic layer OR is, in the X-Z plane, formed into an approximately dome shape including a rounded upper end portion on an opposite side to the tip of the arrow along the first direction X, and a rounded upper end portion on a side of the tip of the arrow along the first direction X. Note that the cross-section of the organic layer OR may be, in the X-Z plane, formed into a shape other than an approximately dome shape. The organic layer OR covers the lower electrode E1 and the insulating layer 11. Note that the organic layer OR may cover the lower electrode El. The organic layer OR includes an organic layer OR2. The organic layer OR2 includes a side portion ORS1 on an opposite side to the tip of the arrow in the first direction X and a side portion ORS2 on a side of the tip of the arrow in the first direction X. The side portion ORS1 is equivalent to the portion from the side surface of the organic layer OR2, on an opposite side to the tip of the arrow in the first direction X to the end portion of the upper surface of the organic layer OR2, on an opposite side to the tip of the arrow in the first direction X. The side portion ORS2 is equivalent to the portion from the side surface of the organic layer OR2, on a side to the tip of the arrow in the first direction X to the end portion of the upper surface of the organic layer OR2, on a side to the tip of the arrow in the first direction X. For example, the organic layer OR2 covers the lower electrode E12 and the insulating layer 11. Note that the organic layer OR2 may cover only the lower electrode E12. The organic layer OR2 covers the upper bottom EU1, the side portion ES11 and the side portion ES12. For example, the organic layer OR2 covers the transparent electrode TE2. In other words, the organic layer OR2 is disposed on the transparent electrode TE2.

In the example shown in FIG. 11, the insulating layer 12 covers the organic layer OR. The insulating layer 12 includes insulating layers 1212 and 1213. For example, the insulating layer 1212 covers the side portion ORS1 of the organic layer OR2. In other words, the insulating layer 1212 is in contact with the side portion ORS1. The insulating layer 1213 covers the side portion ORS2 of the organic layer OR2. In other words, the insulating layer 1213 is in contact with the side portion ORS2.

In the example shown in FIG. 11, the upper electrode E2 is disposed on the insulating layer 12 and the organic layer OR. For example, the upper electrode E2 is disposed on the insulating layer 1212, the organic layer OR2 and the insulating layer 1213.

In the example shown in FIG. 11, the lower electrode E1 is formed, and thereafter, the organic layer OR is deposited on the lower electrode E1 and the organic layer OR is subjected to patterning by dry etching. Then, the resultant is planarized, and the insulating layer 12 is applied on the organic layer OR and the insulating layer 11. Then, patterning is carried out to remove the insulating layer 12 on the organic layer OR. The upper electrode E2 is then deposited on the organic layer OR and the insulating layer 12.

In the second embodiment as well, advantageous effects similar to those of the first embodiment can be obtained.

### Modified Example 6

The display device DSP of Modified Example 6 is different from the display device DSP of each of the embodiment described above and the modified examples thereof in the configurations of the organic layer OR and the insulating layer 12.

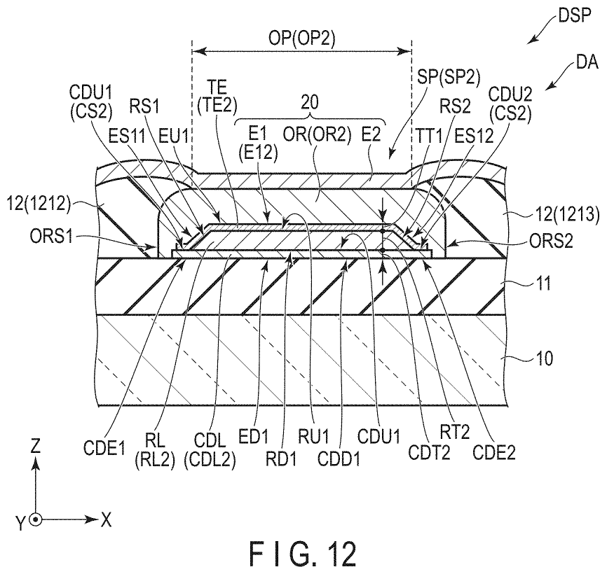

FIG. 12 is a cross-sectional view showing a configuration example of a display device 20 according to Modified Example 6. FIG. 12 illustrates only the configuration necessary for explanation.

In the example shown in FIG. 12, the lower electrode E1 corresponds to the lower electrode E1 shown in FIG. 6. In the example shown in FIG. 12, the organic layer OR2 covers the upper bottom EU1 and the side portions ES11 and ES12 of the lower electrode E12. The organic layer OR2 covers the upper bottom EU1, the reflective layer TE2 which covers the side portion RS1 and the upper surface CDE1 of the reflective layer RL2, the transparent electrode TE2 which covers the end portion CDS1 of the conductive layer CDL2, the side portion RS2 and the upper surface CDE2 of the reflective layer RL2, and the end portion CDS2 of the conductive layer CDL2.

In the example shown in FIG. 12, the insulating layer 12 corresponds to the insulating layer 12 shown in FIG. 11.

In Modified Example 6 as well, advantageous effects similar to those of the second embodiment can be obtained.

### Modified Example 7

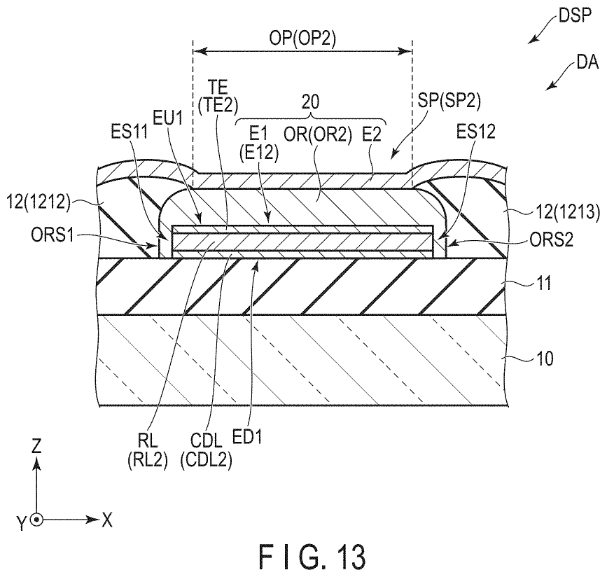

The display device DSP of Modified Example 7 is different from the display device DSP of each of the embodiment described above and the modified examples thereof in the configurations of the organic layer OR and the insulating layer 12. FIG. 13 is a cross-sectional view showing a configuration example of a display device 20 of Modified Example 7. FIG. 13 illustrates only the configuration necessary for explanation.

In the example shown in FIG. 13, the lower electrode E1 corresponds to the lower electrode El shown in FIG. 7. In the example shown in FIG. 13, the organic layer OR2 covers the upper surface EU1 and the side portions ES11 and ES12 of the lower electrode E12. The organic layer OR2 covers the upper surface of the transparent electrode TE2, the side portion of the conductive layer CDL2, on an opposite side to the tip of the arrow along the first direction X, the side portion of the reflective layer RL2, on an opposite side to the tip of the arrow along the first direction X, the side portion of the conductive layer CDL2, on a side to the tip of the arrow along the first direction X, the side portion of the reflective layer RL2, on a side to the tip of the arrow along the first direction X, and the side portion of the transparent electrode TE2, on a side to the tip of the arrow along the first direction X.

In the example shown in FIG. 13, the insulating layer 12 corresponds to the insulating layer 12 shown in FIG. 11.

In Modified Example 7 as well, advantageous effects similar to those of the second embodiment can be obtained.

### Modified Example 8

The display device DSP of Modified Example 8 is different from the display device DSP of each of the embodiment described above and the modified examples thereof in the configurations of the organic layer OR and the insulating layer 12.

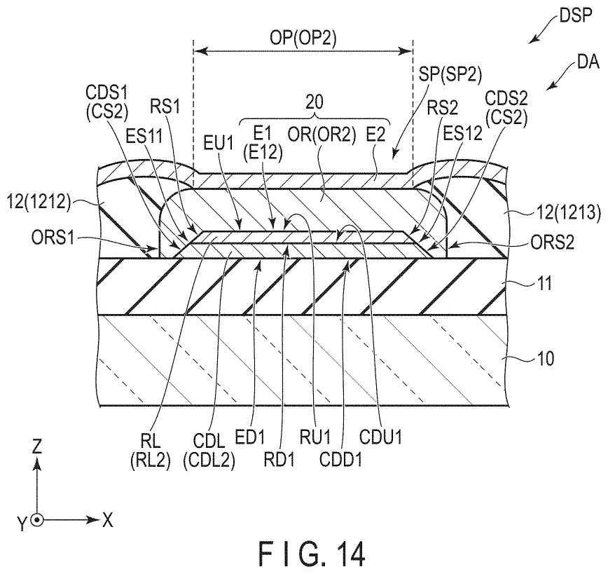

FIG. 14 is a cross-sectional view showing a configuration example of a display device 20 according to Modified Example 8. FIG. 14 illustrates only the configuration necessary for explanation.

In the example shown in FIG. 14, the lower electrode E1 corresponds to the lower electrode E1 shown in FIG. 8.

In the example shown in FIG. 14, the organic layer OR2 covers the upper bottom EU1 and the side portions ES11 and ES12 of the lower electrode E12. The organic layer OR2 covers the upper bottom RU1 of the reflective layer RL2, the side portion RS1 and the side portion RS2 of the reflective layer RL2 and the side portions ES1 and ES12 of the conductive layer CDL2.

In the example shown in FIG. 14, the insulating layer 12 corresponds to insulating layer 12 shown in FIG. 11.

In the example shown in FIG. 14, the transparent electrode (for example, ITO) TE2 is not disposed on the reflective layer (for example, Al or Al alloy) RL2. With this structure, even if alkaline liquid (for example, developer solution) enters during patterning of the organic layer OR2 and the insulating layer 12, deterioration of pixels PX, rise in applied voltage and degradation over time, which may be caused by the reduction of the reflective layer RL2 and the transparent electrode TE2 will not occur. In this manner, a brightness efficiency, which is close to that of the display device DSP including a lower electrode E1, in which the transparent electrode TE2 is disposed on the reflective layer RL2, can be realized. Further, since the area of the reflective layer RL2 can be expanded, the aperture ratio can be improved.

In Modified Example 8 as well, advantageous effects similar to those of the second embodiment can be obtained.

Based on the display device which has been described in the above-described embodiments, a person having ordinary skill in the art may achieve a display device with an arbitral design change; however, as long as they fall within the scope and spirit of the present invention, such a display device is encompassed by the scope of the present invention.

A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the examples described in the above embodiments, any advantage and effect those will be obvious from the description of the specification or arbitrarily conceived by a skilled person are naturally considered achievable by the present invention.

What is claimed is:

1. A display device comprising:
a base;
a first insulating layer disposed on the base;
a lower electrode disposed on the first insulating layer;
an organic layer disposed on the lower electrode and including a light-emitting layer; and
an upper electrode disposed on the organic layer, wherein
the lower electrode comprises,
a conductive layer including a contact area disposed over an entire circumference thereof when viewed in plan view,
a reflective layer disposed above the conductive layer on an inner side of the contact area, which reflects light, and
a transparent electrode located on the conductive layer and the reflective layer and in contact with the contact area.

2. The display device of claim 1, wherein
the reflective layer has a cross-section including an upper surface, a first inclined surface expanding downward from the upper surface, and a second inclined surface expanding downward from the upper surface and located on an opposite side to the first inclined surface, and
the first inclined surface, the second inclined surface and the upper surface are covered by the transparent electrode.

3. The display device of claim 2, wherein
the conductive layer has a cross-section including a third inclined surface continuous to the first inclined surface and located on an outer side of the first inclined surface and a fourth inclined surface continuous to the second inclined surface and located on an outer side of the second inclined surface, and
the third inclined surface and the fourth inclined surface are equivalent to the contact area and are in contact with the transparent electrode.

4. The display device of claim 3, wherein
the cross-section of the conductive layer is formed into a trapezoidal shape.

5. The display device of claim 2, wherein
the cross-section of the conductive layer includes a first end portion located on an outer side of the first inclined surface and a second end portion located on an outer side of the second inclined surface, and
a first upper surface of the first end portion and a second upper surface of the second end portion correspond to the contact area and are in contact with the transparent electrode.

6. The display device of claim 5, wherein
the cross-section of the conductive layer is formed into a rectangular shape.

7. The display device of claim 1, further comprising:
a second insulating layer disposed on the first insulating layer; and
a third insulating layer disposed on the first insulating layer,
wherein
the lower electrode has a cross-section including a fifth inclined surface expanding downward and a sixth inclined surface expanding downward and located on an opposite side to the fifth inclined surface,
the second insulating layer covers the fifth inclined surface, and
the third insulating layer covers the sixth inclined surface.

8. The display device of claim 7, wherein
the organic layer is disposed on the second insulating layer, the lower electrode and the third insulating layer.

9. The display device of claim 1, wherein
the organic layer covers the lower electrode.

10. The display device of claim 1, further comprising:
a second insulating layer disposed on the first insulating layer; and
a third insulating layer disposed on the first insulating layer,
wherein
the organic layer includes a first side portion and a second side portion located on an opposite side to the first side portion,
the second insulating layer is in contact with the first side portion, and
the third insulating layer is in contact with the second side portion.

11. The display device of claim 10, wherein
the upper electrode is disposed on the second insulating layer, the organic layer and the third insulating layer.

12. The display device of claim 1, wherein
the transparent electrode is formed of indium tin oxide, and
the reflective layer is formed of aluminum or an aluminum alloy.

13. The display device of claim 12, wherein
the conductive layer is formed of a metal material containing titanium.

14. A display device comprising:
a base;
a first insulating layer disposed on the base;
a lower electrode disposed on the first insulating layer;
an organic layer disposed on the lower electrode and including a light-emitting layer; and
an upper electrode disposed on the organic layer, wherein
the lower electrode includes a conductive layer, a reflective layer disposed on the conductive layer, which reflects light, and a transparent electrode disposed on the reflective layer,
the transparent electrode is formed of indium tin oxide, and
the reflective layer is formed of Al—Ni, Al—W alloy, Al—Mo alloy, Al—Ti alloy, Al—Ni—W, Al—Ni—Mo alloy or Al—Ni—Ti alloy.

15. The display device of claim 14, further comprising:
a second insulating layer disposed on the first insulating layer; and
a third insulating layer disposed on the first insulating layer,
wherein
the lower electrode has a cross-section including a first side portion and a second side portion on an opposite side to the first side portion,
the second insulating layer covers the first side portion, and
the third insulating layer covers the second side portion.

16. The display device of claim 14, wherein
the organic layer covers the lower electrode.

17. The display device of claim 16, further comprising:
a second insulating layer disposed on the first insulating layer; and
a third insulating layer disposed on the first insulating layer,
wherein
the organic layer includes a first side portion and a second side portion on an opposite side to the first side portion,
the second insulating layer is in contact with the first side portion, and
the third insulating layer is in contact with the second side portion.
